(19) United States
(12) Patent Application Publication
(10) Pub. No.: US 2025/0336680 A1
(43) Pub. Date: Oct. 30, 2025

(54) THIN FILM, METHOD OF FORMING THE SAME AND SEMICONDUCTOR DEVICE

(71) Applicants: SAMSUNG ELECTRONICS CO., LTD., Suwon-si (KR); AJOU UNIVERSITY INDUSTRY-ACADEMIC COOPERATION FOUNDATION, Suwon-si (KR)

(72) Inventors: Kijung Jung, Suwon-si (KR); Sang Woon Lee, Suwon-si (KR); Seung-Yeon KWAK, Suwon-si (KR); Hwea Yoon KIM, Suwon-si (KR); YONGSUK CHO, Suwon-si (KR); Jong Won CHOI, Suwon-si (KR); Se Eun Kim, Suwon-si (KR); Yewon Yun, Suwon-si (KR); Byeongjun Jeon, Suwon-si (KR)

(21) Appl. No.: 19/005,351

(22) Filed: Dec. 30, 2024

(30) Foreign Application Priority Data
Apr. 26, 2024 (KR) 10-2024-0056175

(51) Int. Cl. H01L 21/285; C23C 16/04; C23C 16/34; C23C 16/455; H10D 64/27

(52) U.S. Cl. CPC H01L 21/28568; C23C 16/045; C23C 16/34; C23C 16/45527; C23C 16/45553; H10D 64/513

(57) ABSTRACT

A method for forming a thin film includes supplying a precursor including a metal or semi-metal element and a first halogen onto a substrate configured for a semiconductor device, supplying an inorganic additive including a second halogen different from the first halogen and excluding iodine and configured to spontaneously substitute the first halogen of the precursor at a predetermined temperature, and supplying a reactant configured to chemically bond to the metal or semi-metal element, forming the thin film.

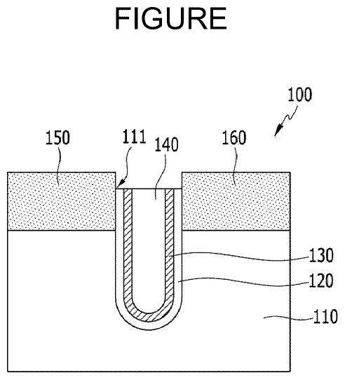

### CROSS-REFERENCE TO RELATED APPLICATION

This application claims priority to and the benefit of Korean Patent Application No. 10-2024-0056175 filed in the Korean Intellectual Property Office on Apr. 26, 2024, and all benefits accruing therefrom under 35 U.S.C. § 119 the content of which in its entirety is herein incorporated by reference.

### BACKGROUND

### 1. Field

Thin films, methods of forming the thin films, and semiconductor devices including the thin films are disclosed.

### 2. Description of the Related Art

The process by which various thin films are deposited is important in the manufacture of memory or non-memory semiconductor devices. Recently, as the structure of integrated circuit devices has become increasingly miniaturized and more complex, various technologies for depositing high-quality thin films are being studied.

### SUMMARY

One method for depositing a thin film inside a semiconductor device includes supplying a precursor for forming the thin film.

However, residues derived from the precursor for forming the thin film may act as impurities in subsequent processes for producing the semiconductor devices and/or as impurities in the semiconductor devices, thereby affecting electrical characteristics of the semiconductor devices.

Accordingly, an embodiment provides a method for forming a thin film that may reduce or prevent performance degradation of a semiconductor device by reducing residue during depositing the thin film.

Another embodiment provides a thin film formed by the method. Another embodiment provides a semiconductor device including the thin film.

According to an embodiment, a method for forming a thin film includes supplying a precursor including a metal or semi-metal element and a first halogen onto a substrate configured for a semiconductor device, supplying an inorganic additive including a second halogen different from the first halogen and excluding iodine (I) and configured to spontaneously substitute the first halogen of the precursor at a predetermined temperature, and supplying a reactant configured to chemically bond to the metal or semi-metal element, forming the thin film.

The first halogen may be fluorine (F), chlorine (Cl), or a combination thereof, and the second halogen may be bromine (Br).

The inorganic additive may include hydrogen bromide (HBr), dibromine (Br₂), or a combination thereof.

The thin film may include a nitride, oxide, or oxynitride including the metal or semi-metal element.

The precursor may be a fluoride or chloride including titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof, and the thin film may include a nitride, oxide or oxynitride including (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof.

The reactant may include ammonia (NH₃), dihydrogen (H₂), water (H₂O), dioxygen (O₂), ozone (O₃), or a combination thereof.

A supplied amount of the inorganic additive may be less than a supplied amount of the precursor.

The predetermined temperature may be a process temperature, and may be about 200° C. to about 600° C.

The supplying of the inorganic additive may be performed before or after the supplying of the precursor.

The method may further include supplying a reaction accelerator including a third halogen, the third halogen being different from the first halogen and the second halogen.

The third halogen may be iodine (I).

The reaction accelerator may include hydrogen iodine (HI), diiodine (I₂), R-I, wherein R is a substituted or unsubstituted C1 to C30 hydrocarbon group and I is iodine, or a combination thereof.

The supplying of the reaction accelerator may be performed before the supplying of the reactant.

The supplying of the precursor, the supplying of the inorganic additive, and the supplying of the reaction accelerator may be sequentially performed.

Each of the supplying of the precursor, the supplying of the inorganic additive, and the supplying of the reactant may be repeated multiple times to form a plurality of atomic layers.

A content of the first halogen in the thin film analyzed by TEM-EDS (transmission electron microscopy with energy-dispersive X-ray spectroscopy) may be less than or equal to about 2.5 atomic percent (at %).

A content of the second halogen in the thin film analyzed by TEM-EDS (transmission electron microscopy with energy-dispersive X-ray spectroscopy) may be less than or equal to about 0.5 atomic percent (at %).

According to another embodiment, a thin film, which may be formed by the above method, includes a nitride, oxide or oxynitride including a metal or semi-metal element, wherein a content of fluorine (F), chlorine (Cl), or a combination thereof is less than or equal to about 2.5 atomic percent (at %), a content of bromine (Br) is less than or equal to about 0.5 atomic percent (at %), and the thin film does not include carbon.

The thin film may include a nitride, oxide or oxynitride including titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof.

According to another embodiment, a semiconductor device including the thin film is provided.

In embodiments, by reducing residues in the thin film deposition, a high-purity thin film may be formed, and performance degradation of semiconductor devices including the thin film may be effectively reduced or prevented.

### BRIEF DESCRIPTION OF THE DRAWING

The above and other advantages and features of this disclosure will become more apparent by describing in further detail exemplary embodiments thereof with reference to the accompanying drawing, in which:

The FIGURE is a cross-sectional view schematically showing an example of a semiconductor device according to an embodiment.

### DETAILED DESCRIPTION

Hereinafter, example embodiments of the present disclosure will be described in detail so that a person skilled in the art would understand the same. The disclosure may, however, be embodied in many different forms and is not construed as limited to the example embodiments set forth herein.

It will be understood that, although the terms “first,” “second,” “third,” etc., may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

In the drawing, the thickness of layers, films, panels, regions, etc., are exaggerated for clarity and like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

The drawing and description are to be regarded as illustrative in nature and not restrictive. Like reference numerals designate like elements throughout the specification.

It will be understood that when a component is referred to as being “on” or “above” another component, the component may be directly on, under, on the left of, or on the right of the other component, or may be on, under, on the left of, or on the right of the other component in a non-contact manner. In addition, unless explicitly described to the contrary, the word “comprise,” and variations such as “comprises” or “comprising,” will be understood to imply the inclusion of stated elements.

The term, “layer” includes a construction having a shape formed on a part of a region, in addition to a construction having a shape formed on an entire region.

The steps of all methods described herein may be performed in any suitable order unless otherwise indicated herein or otherwise clearly contradicted by context.

Herein, “combination thereof” refer to a mixture, a stacked structure, a composite, an alloy, or a blend of constituents.

Furthermore, relative terms, such as “lower” or “bottom” and “upper” or “top,” may be used herein to describe one element's relationship to another element as illustrated in the Figure. It will be understood that relative terms are intended to encompass different orientations of the device in addition to the orientation depicted in the Figure. For example, if the device is turned over, elements described as being on the “lower” side of other elements would then be oriented on “upper” sides of the other elements. The term “lower,” can therefore, encompasses both an orientation of “lower” and “upper,” depending on the particular orientation. Similarly, if the device is turned over, elements described as “below” or “beneath” other elements would then be oriented “above” the other elements. The terms “below” or “beneath” can, therefore, encompass both an orientation of above and below.

Herein, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Herein, “semi-metal” is interpreted as including metalloids.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figure are schematic in nature and their shapes are not intended to illustrate the precise shape of a region and are not intended to limit the scope of the present claims.

Herein, a method for forming a thin film according to an embodiment is described.

A thin film may include a conductor, a semiconductor, or an insulator that may be included in a semiconductor device. In an embodiment, for example, the thin film may include a layer or film of nanometer (nm) to micrometer (μm) thickness that performs electrical and/or chemical functions in the semiconductor device. The thin film may be a deposited thin film formed by a deposition process such as atomic layer deposition (ALD) or chemical vapor deposition (CVD), but is not limited thereto.

In an embodiment, for example, the thin film may include a nitride, oxide, or oxynitride including a metal or semi-metal element, and may be used as a wiring, contact layer, adhesive layer, diffusion barrier film, dielectric layer, interlayer insulating film, passivation film, or a combination thereof, but is not limited thereto, and thus may be used as other components of semiconductor devices.

A method for forming a thin film according to an embodiment includes supplying a precursor onto a substrate in a deposition chamber, supplying an inorganic additive to the deposition chamber, and supplying a reactant to the deposition chamber.

First, the precursor is supplied onto the substrate in the deposition chamber.

The deposition chamber may be maintained at a relatively low pressure (e.g., about 0.1 torr to about 2 torr) during deposition and may be connected to a pressure control pump (e.g., a vacuum pump) for the relatively low pressure. Additionally, the deposition chamber may be connected to a precursor supply unit for supplying a precursor, a reactant supply unit for supplying a reactant, and a purge gas supply unit for supplying a purge gas, which will be further described below.

In an embodiment, for example, the substrate may be a semiconductor substrate, and one or more layers and/or structures may be formed inside and/or on top of the semiconductor substrate. The semiconductor substrate may include, for example, a Group IV semiconductor material, a Group III-V semiconductor compound, or a Group II-VI semiconductor compound. In an embodiment, for example, the semiconductor substrate may include a Group IV semiconductor material including at least one or more of silicon (Si), germanium (Ge), tin (Sn), and carbon (C), a Group III-V compound semiconductor material in which at least one or more of boron (B), gallium (Ga), indium (In), and aluminum (Al) are bonded with at least one or more of nickel (N), phosphorus (P), arsenic (As), antimony (Sb), sulfur (S), selenium (Se), and tellurium (Te), or a Group II-VI compound semiconductor material in which at least one or more of beryllium (Be), magnesium (Mg), cadmium (Cd), and zinc (Zn) are bonded with at least one or more of oxygen (O), sulfur (S), selenium (Se), and tellurium (Te). In an embodiment, for example, the semiconductor substrate may include silicon (Si), germanium (Ge), silicon carbide (SiC), silicon germanium (SiGe), silicon germanium carbide (SiGeC), germanium (Ge) alloys, gallium tin (GaAs), indium arsenide (InAs), indium phosphide (InP), and the like, but is not limited thereto.

The substrate surface temperature during deposition may be at a temperature of the process temperature (deposition temperature), for example, about 200° C. to about 600° C., and within this range may be about 250° C. to about 550° C., about 300° C. to about 500° C., or about 350° C. to about 450° C.

The precursor may be supplied in a vapor state in the deposition chamber, and the method may further include converting the precursor in a liquid state at room temperature into a vapor state.

The precursor may be a material configured to be chemically adsorbed onto the surface of the substrate or onto one or more layers and/or structures in and/or on the substrate, and the precursor may be configured to chemically bind or adsorb the reactant, as further described below. The precursor may be a material that supplies a metal or semi-metal element to the thin film.

In an embodiment, the precursor includes a metal or semi-metal element and a first halogen.

The type of metal or semi-metal element may be selected depending on the role of the thin film and may include, for example, titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof, but is not limited thereto. The first halogen may be a ligand chemically bonded to a metal or semi-metal element, or may be included in a ligand. In an embodiment, the first halogen may be fluorine (F), chlorine (Cl), or a combination thereof. Accordingly, in an embodiment, the precursor may be a fluoride or chloride, for example, including titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof.

The number of ligands may be determined depending on the metal or semi-metal element and may be, for example, from two (2) to six (6). At least one of the ligands may include a first halogen, for example, the number of first halogens in the precursor may be from one (1) to six (6). Some of the ligands may not be the first halogen and may be selected from, for example, —H, αO, —R¹, —OR¹, —NR¹, wherein R¹ is a same or different C1 to C30 hydrocarbon group, or a combination thereof. In an embodiment, for example, each ligand may be an inorganic ligand and optionally further include a first halogen and —H, ═O, or a combination thereof. In an embodiment, for example, the precursor may be titanium tetrachloride (TiCl₄), tantalum tetrachloride (TaCl₄), zirconium tetrachloride (ZrCl₄), tungsten hexafluoride (WF₆), hafnium tetrachloride (HfCl₄), or molybdenum dichloride dioxide (MoO₂Cl₂), but is not limited thereto.

The precursor may be supplied into the deposition chamber for, for example, about 0.1 seconds to about 2 seconds, but is not limited thereto.

Next, a purge gas may be supplied into the deposition chamber to discharge excess precursors and/or its byproducts. The purge gas may be an inert gas, such as argon gas, nitrogen gas, or a combination thereof, but is not limited thereto. In an embodiment, the purge gas may be supplied at a flow rate of, for example, about 200 standard cubic centimeters per minute (sccm) to about 600 standard cubic centimeters per minute (sccm) for about 5 seconds to about 20 seconds, but is not limited thereto.

Next, in an embodiment, the inorganic additive is supplied into the deposition chamber. The inorganic additive may be supplied in a gaseous state in the deposition chamber, and the method may further include converting the inorganic additive in a liquid state at room temperature into a gaseous state.

The inorganic additive may include a component capable of spontaneously substituting the first halogen of the precursor at a predetermined temperature, for example, a component capable of dissociating a bond between the metal or semi-metal element and the first halogen and spontaneously bonding to the metal or semi-metal element. The predetermined temperature may be a process temperature (deposition temperature) and/or a substrate temperature, for example, about 200° C. to about 600° C., and within that range about 250° C. to about 550° C., about 300° C. to about 500° C., or from about 350° C. to about 450° C.

The inorganic additive may include a second halogen different from the first halogen. The second halogen may be bromine (Br), and the inorganic additive may include hydrogen bromide (HBr), dibromine (Br₂) or a combination thereof. In an embodiment, the second halogen may not be iodine (I).

In an embodiment, for example, when an inorganic additive including (e.g., HBr) and/or (e.g., Br₂) is supplied to a precursor including a metal or semi-metal element and the first halogen (e.g., F and/or Cl), the Gibbs free energy (ΔG) has a negative value at about 200 K to about 1000 K (a temperature range including the process temperature). Thus, in an embodiment, spontaneous decomposition of (e.g., HBr) and/or (e.g., Br₂) and spontaneous substitution of bromine (e.g., Br) at the position of the first halogen (e.g., F and/or Cl) bonded to the metal or semi-metal element may occur. That is, in an embodiment, the metal or semi-metal element may be bonded with the second halogen (e.g., Br), and the first halogen (e.g., F and/or Cl) may be separated from the metal or semi-metal element.

In an embodiment, for example, when the precursor is titanium tetrachloride (TiCl₄) and the inorganic additive is dibromine (Br₂), the Gibbs free energy (ΔG₁) of the reaction of the titanium tetrachloride (TiCl₄) and bromide (Br₂) has a negative value of about −420 kilojoules per mol (KJ/mol) to about −400 kilojoules per mol (KJ/mol) in the temperature range including the process temperature, and from this, it may be expected that Reaction Scheme 1 occurs spontaneously.

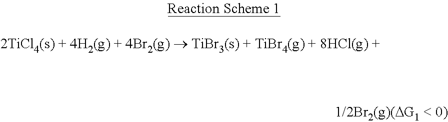

According to Reaction Scheme 1, a metal or semi-metal element (e.g., Ti) and a second halogen (e.g., Br) may exist in a bonded state (e.g., solid-state TiBr₃) on the substrate surface (or on one or more layers and/or structures located inside and/or on the substrate), and the first halogen (e.g., Cl) may be separated from the metal or semi-metal element and exist in a gaseous state in the deposition chamber.

In an embodiment, a supplied amount of the inorganic additive may be less than a supplied amount of the precursor as mentioned above, for example, the supplied amount of the precursor to the supplied inorganic additive may be greater than about 1:1 and less than or equal to about 10:1, and within the above range, may be greater than about 1:1 and less than or equal to about 7:1 or greater than about 1:1 and less than or equal to about 5:1.

Here, the supplied amounts of inorganic additive and precursors may be controlled by flow rate and/or supply time. In the above embodiment, it has been described that the supply of the inorganic additive is performed after the supply of the precursor, but this is not limited thereto, and the inorganic additive may be supplied first before the supply of the precursor. In this case, the inorganic additive may exist in a gaseous state in the deposition chamber, and the afore-mentioned spontaneous substitution reaction may occur by the supply of the precursors. As described above, spontaneous decomposition of (e.g., HBr) and/or (e.g., Br₂) and spontaneous substitution of bromine (e.g., Br) at the first halogen (e.g., F and/or Cl) position bonded to the metal or semi-metal element may occur.

In an embodiment, the inorganic additive may be supplied at a flow rate of, for example, about 20 sccm to about 100 sccm for about 0.1 seconds to about 2 seconds, but is not limited thereto.

Next, a purge gas may be supplied into the deposition chamber to discharge residues and byproducts from the deposition chamber. The residue may include a first halogen or a first halogen-containing material (e.g., fluorine (F), chlorine (Cl), hydrogen fluoride (HF), and/or hydrogen chloride (HCl)) separated by the spontaneous substitution described above. The purge gas may be an inert gas, such as argon gas, nitrogen gas, or a combination thereof, but is not limited thereto. The purge gas may be supplied at a flow rate of, for example, about 200 sccm to about 2000 sccm for about 5 seconds to about 10 seconds, but is not limited thereto.

Next, the reactant may be supplied into the deposition chamber. The reactant may be supplied in a gaseous state in the deposition chamber, and the method may further include converting the reactant of a liquid state at room temperature into a gaseous state.

The reactant may be a substance capable of chemically bonding to a metal or semi-metal element, and may supply oxygen and/or nitrogen to form a component other than the metal or semi-metal in the thin film, such as an oxide, nitride, or oxynitride.

The reactant may include a component capable of spontaneously substituting the second halogen (e.g., Br) at a predetermined temperature, for example, a component capable of dissociating a bond between a metal or semi- metal element and the second halogen (e.g., Br) and spontaneously bonding with the metal or semi-metal element. In an embodiment, for example, the reactant may have a higher degree of substitution with the second halogen (e.g., Br) than with the first halogen (e.g., F and/or Cl). The predetermined temperature may be a process temperature (deposition temperature) and/or a substrate temperature, for example, from about 200° C. to about 600° C., and within that range from about 250° C. to about 550° C., from about 300° C. to about 500° C., or from about 350° C. to about 450° C.

The reactant may be a reactant gas, including but not limited to, ammonia (NH₃), dihydrogen (H₂), water (H₂O), oxygen (O₂), ozone (O₃), or a combination thereof. The reactant may be supplied at a flow rate of, for example, about 50 sccm to about 600 sccm for about 2 seconds to about 10 seconds, but is not limited thereto.

In an embodiment, for example, when the reactant is supplied into a deposition chamber including a metal or semi-metal element and a second halogen (e.g., Br), the Gibbs free energy (ΔG₂) has a negative value, and accordingly, the bond between the metal or semi-metal element and the second halogen (e.g., Br) is spontaneously decomposed, and spontaneous substitution of an element (e.g., N or O) of the reactant may occur at the position of the second halogen (e.g., Br) bonded to the metal or semi-metal element. That is, in an embodiment, the metal or semi-metal element may be bonded with nitrogen (e.g., N) or oxygen (e.g., O), and the second halogen (e.g., Br) may be separated from the metal or semi-metal element.

In an embodiment, for example, when precursor TiCl₄, inorganic additive Br₂, and reactant NH₃ are used, the Gibbs free energy (ΔG₂) of the reaction of TiBr₃ and NH₃ according to the afore-mentioned reaction scheme 1 has a negative value of about −100 KJ/mol to about −10 KJ/mol, and from this, it may be expected that Reaction Scheme 2 occurs spontaneously.

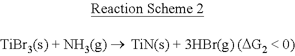

According to Reaction Scheme 2, a metal or semi-metal element (e.g., Ti) and an element (e.g., N) derived from the reactant may exist in a bonded state (e.g., solid-state TiN) on the substrate surface (or on one or more layers and/or structures located inside and/or on the substrate), and a second halogen (e.g., Br) may be separated from the metal or semi-metal element and exist in a gaseous state in the deposition chamber.

If the precursor including the first halogen (e.g., F and/or Cl) is directly reacted with the reactant without supplying the afore-mentioned inorganic additive, the high bond dissociation energy between the metal or semi-metal element in the precursor and the first halogen (e.g., F and/or Cl) may not sufficiently cause a spontaneous reaction, and thus some of the first halogen (e.g., F and/or Cl) in the precursor may remain bonded to the metal or semi-metal element. These primary halogens (e.g., F and/or Cl) may ultimately remain in the thin film and act as impurities.

In contrast, in an embodiment, by sequentially performing a spontaneous substitution reaction of the first halogen (e.g., F and/or Cl) into the second halogen (e.g., Br) by the inorganic additive (e.g., Reaction Scheme 1) before supplying the reactant to the deposition chamber, as described above, and a spontaneous substitution reaction of the second halogen (e.g., Br) with the reactant (e.g., Reaction Scheme 2), the first halogen (e.g., F and/or Cl) may be effectively separated from the metal or semi-metal element while facilitating its substitution with the reactant, thereby effectively reducing or eliminating the first halogen (e.g., F and/or Cl) and the second halogen (e.g., Br). Accordingly, the residues of the first halogen (e.g., F and/or Cl) and the second halogen (e.g., Br) remaining in the thin film may be advantageously, effectively reduced or eliminated, thereby effectively reducing impurities in the thin film.

Next, a purge gas may be supplied into the deposition chamber to discharge residues and byproducts from the deposition chamber. The residue may include the second halogen or the second halogen-containing material (e.g., Br and/or HBr) separated by the spontaneous substitution described above. The purge gas may be an inert gas, such as argon gas, nitrogen gas, or a combination thereof, but is not limited thereto. The purge gas may be supplied at a flow rate of, for example, about 200 sccm to about 600 sccm for about 5 seconds to about 20 seconds, but is not limited thereto.

In an embodiment the supplying of the precursor, the supplying of the inorganic additive, the supplying of the reactant, and the purging between each process constitute one (1) cycle, and multiple cycles may be performed to form a thin film of a predetermined thickness. The number of cycles may be determined depending on the desired thickness of the thin film, and a thin film having an atomic-level thickness may be formed by one (1) cycle. A thin film having a thickness of, for example, about 0.2 nanometers (nm) to about 500 nanometers (nm) may be formed by multiple cycles. In such an embodiment, a thin film may have a thickness of, for example, about 0.4 nm to about 400 nm, for example, about 0.6 nm to about 300 nm, for example, about 0.8 nm to about 200 nm, for example, about 1 nm to about 100 nm, for example, about 1.2 nm to about 80 nm, for example, about 1.4 nm to about 60 nm, for example, about 1.6 nm to about 40 nm, for example, about 1.8 nm to about 20 nm, and, for example, about 2 nm to about 10 nm.

Hereinafter, a method for forming a thin film according to another embodiment is described.

A method for forming a thin film according to another embodiment includes, similarly to the above-described embodiment, supplying a precursor onto a substrate in a deposition chamber, supplying an inorganic additive, and supplying a reactant. The descriptions of the precursor, inorganic additive, and reactant are as described above.

However, unlike the above-described embodiment, the method for forming a thin film according to another embodiment may further include supplying a reaction accelerator before the supplying of the reactant.

The reaction accelerator may be a substance configured to enhance the bonding reaction of a reactant to a metal or semi-metal element. In an embodiment, the reaction accelerator may include, for example, a third halogen that is different from the first halogen (e.g., F and/or CI) and the second halogen (e.g., Br). In an embodiment, the third halogen may be, for example, iodine (I), and the reaction accelerator may include, for example, HI, I₂, R-I, wherein R is a substituted or unsubstituted C1 to C30 hydrocarbon group, or a combination thereof. In an embodiment, the reaction accelerator may be, for example, HI, I₂, or a combination thereof. The reaction accelerator may be supplied at a flow rate of, for example, about 50 sccm to about 300 sccm for about 0.1 seconds to about 10 seconds, but is not limited thereto.

In an embodiment, the reaction accelerator may be supplied before the supplying of the reactant, for example, it may be supplied between the supplying of the inorganic additive and the supplying of the reactant. In an embodiment, for example, it may be performed in the order of the supplying of the precursor, the supplying of the inorganic additive, and supplying of the reaction accelerator. Accordingly, instead of directly replacing the second halogen (e.g., Br) of the inorganic additive with the reactant, the second halogen (e.g., Br) of the inorganic additive may be first replaced with the third halogen (e.g., I) of the reaction accelerator, and then the third halogen (e.g., I) may be replaced with the reactant. This sequential reaction may further increase reactivity, effectively reducing the flow rate and/or supply time of the reactants, while also further reducing the residues.

After supplying the reaction accelerator, a purge gas may be supplied into the deposition chamber to discharge residues and byproducts from the deposition chamber. The residue may include the second halogen or the second halogen-containing material (e.g., Br and/or HBr) separated by the spontaneous substitution described above. The purge gas may be an inert gas, such as argon gas, nitrogen gas, or a combination thereof, but is not limited thereto. The purge gas may be supplied at a flow rate of, for example, about 200 sccm to about 2000 sccm for about 5 seconds to about 20 seconds, but is not limited thereto.

In an embodiment, the thin film formed by the above-described method may be a nitride, oxide, or oxynitride including a metal or semi-metal element, for example, a nitride, oxide or oxynitride including Ti, Ta, W, Zr, Zn, Mo, Nb, Al, V, Co, Ni, Cu, Hf, La, Ce, Nd, Si, Ge, or a combination thereof, depending on the reactant.

As described above, in an embodiment, by effectively separating the metal or semi-metal element and the first halogen (e.g., F and/or Cl) from the precursor with relatively strong bond dissociation energy by the inorganic additive, and at the same time facilitating their substitution with the reactant, the residues that may act as impurities in the thin film may be effectively reduced or eliminated. Accordingly, a high-purity thin film with reduced impurities may be obtained.

A content of impurities in the thin film may be analyzed by transmission electron microscopy with energy-dispersive X-ray spectroscopy (TEM-EDS).

In an embodiment, for example, the content of the first halogen (e.g., F and/or Cl) in the thin film may be less than or equal to about 2.5 atomic percent (at %), and within the range of greater than or equal to about 0 at % and less than or equal to about 2.3 at %, greater than or equal to about 0 at % and less than or equal to about 2.1 at %, greater than or equal to about 0 at % and less than or equal to about 1.8 at %, greater than or equal to about 0 at % and less than or equal to about 1.5 at %, greater than or equal to about 0 at % and less than or equal to about 1.2 at %, greater than or equal to about 0 at % and less than or equal to about 1.0 at %, greater than or equal to about 0 at % and less than or equal to about 0.8 at %, greater than or equal to about 0 at % and less than or equal to about 0.5 at %, greater than or equal to about 0 at % and less than or equal to about 0.3 at %, greater than or equal to about 0 at % and less than or equal to about 0.2 at %, greater than or equal to about 0 at % and less than or equal to about 0.1 at %, greater than or equal to about 0.01 at % and less than or equal to about 2.5 at %, greater than or equal to about 0.01 at % and less than or equal to about 2.3 at % or less, about 0.01 or more and about 2.1 at %, greater than or equal to about 0.01 at % and less than or equal to about 1.8 at %, greater than or equal to about 0.01 at % and less than or equal to about 1.5 at %, greater than or equal to about 0.01 at % and less than or equal to about 1.2 at %, greater than or equal to about 0.01 at % and less than or equal to about 1.0 at %, greater than or equal to about 0.01 at % and less than or equal to about 0.8 at %, greater than or equal to about 0.01 at % and less than or equal to about 0.5 at %, greater than or equal to about 0.01 at % and less than or equal to about 0.3 at %, greater than or equal to about 0.01 at % and less than or equal to about 0.2 at %, or greater than or equal to about 0.01 at % and less than or equal to about 0.1 at %.

In an embodiment, for example, the content of the second halogen (e.g., Br) in the thin film may be less than or equal to about 0.5 at %, and within the range may be greater than or equal to about 0 at % and less than or equal to about 0.4 at %, greater than or equal to about 0 at % and less than or equal to about 0.3 at %, greater than or equal to about 0 at % and less than or equal to about 0.2 at %, greater than or equal to about 0 at % and less than or equal to about 0.1 at %, greater than or equal to about 0.01 at % and less than or equal to about 0.5 at %, greater than or equal to about 0.01 at % and less than or equal to about 0.4 at %, greater than or equal to about 0.01 at % and less than or equal to about 0.3 at %, greater than or equal to about 0.01 at % and less than or equal to about 0.2 at %, or greater than or equal to about 0.01 at % and less than or equal to about 0.1 at %.

In an embodiment, for example, the content of the second halogen (e.g., Br) in the thin film may be less than or equal to about 5000 parts per million (ppm), and within the range of greater than or equal to about 0 ppm and less than or equal to about 4000 ppm, greater than or equal to about 0 ppm and less than or equal to about 3000 ppm, greater than or equal to about 0 ppm and less than or equal to about 2000 ppm, greater than or equal to about 0 ppm and less than or equal to about 1000 ppm, greater than or equal to about 0 ppm and less than or equal to about 800 ppm, greater than or equal to about 0 ppm and less than or equal to about 500 ppm, greater than or equal to about 0 ppm and less than or equal to about 300 ppm, greater than or equal to about 0 ppm and less than or equal to about 200 ppm, greater than or equal to about 0 ppm and less than or equal to about 100 ppm, greater than or equal to about 0 ppm and less than or equal to about 50 ppm, greater than or equal to about 0 ppm and less than or equal to about 30 ppm, greater than or equal to about 0 ppm and less than or equal to about 20 ppm, greater than or equal to about 0 ppm and less than or equal to about 10 ppm, greater than or equal to about 0 ppm and less than or equal to about 5 ppm, greater than or equal to about 0 ppm and less than or equal to about 3 ppm, or greater than or equal to about 0 ppm and less than or equal to about 1 ppm, greater than about 0 and about 5000 ppm, greater than about 0 and about 4000 ppm, greater than about 0 ppm and less than about 3000 ppm, greater than about 0 ppm and less than about 2000 ppm, greater than about 0 ppm and less than about 1000 ppm, greater than about 0 ppm and less than about 800 ppm, greater than about 0 ppm and less than about 500 ppm, greater than about 0 ppm and less than about 300 ppm, greater than about 0 ppm and less than about 200 ppm, greater than about 0 ppm and less than about 100 ppm, greater than about 0 ppm and less than about 50 ppm, greater than about 0 ppm and less than about 30 ppm, greater than about 0 ppm and less than about 20 ppm, greater than about 0 ppm and less than about 10 ppm, greater than about 0 ppm and less than about 5 ppm, greater than about 0 ppm and less than about 3 ppm, or greater than about 0 ppm and less than about 1 ppm.

In an embodiment, for example, the purity of the thin film may be greater than or equal to about 98%, greater than or equal to about 98.5%, greater than or equal to about 99%, greater than or equal to about 99.5%, greater than or equal to about 99.7%, greater than or equal to about 99.8%, or greater than or equal to about 99.9%. Herein, purity may be a percentage of the number of metal or semi-metal elements included in the precursor and nitrogen and/or oxygen elements included in the reactant among the number of all elements forming the thin film.

In addition, in an embodiment, the thin film formed by the above-described method may effectively prevent the influence of electrical properties due to carbon residue by not including carbon in the precursor, inorganic additive, and reactant, respectively.

In an embodiment, for example, the thin film formed by the method described above may include a nitride, oxide or oxynitride including a metal or semi-metal element, and may satisfy a first halogen (e.g., F and/or Cl) content of less than or equal to about 2.5 at % and a second halogen (e.g., Br) content of less than or equal to about 0.5 at %, and may not include carbon. Accordingly, the thin film may perform high electrical and/or chemical functions without being affected by impurities.

In an embodiment, the afore-mentioned thin film may be included in a semiconductor device and may be included as, for example, a conductor, a semiconductor, or an insulator. In an embodiment, for example, the afore- mentioned thin film may be used as a wiring, a contact layer, an adhesive layer, a diffusion barrier film, a dielectric layer, an interlayer insulating film, a passivation film, or a combination thereof, or other semiconductor device component.

Hereinafter, a semiconductor device according to an embodiment will be described with reference to the FIGURE.

The FIGURE is a cross-sectional view schematically showing an example of a semiconductor device according to an embodiment.

Referring to the FIGURE, a semiconductor device 100 according to an embodiment may include a substrate 110, a gate insulating film 120, a diffusion barrier film 130, a gate electrode 140, a source electrode 150, and a drain electrode 160. The substrate 110 may be a semiconductor substrate.

In an embodiment, the substrate 110 may include, for example, a Group IV semiconductor material, a Group III-V semiconductor compound, or a Group

II-VI semiconductor compound. For example, the substrate 110 may include a Group IV semiconductor material including at least one or more of Si, Ge, Sn, and C, a Group III-V compound semiconductor material in which at least one or more of B, Ga, In, and Al are bonded with at least one or more of N, P, As, Sb, S, Se, and Te, or a Group II-VI compound semiconductor material in which at least one or more of Be, Mg, Cd, and Zn are bonded with at least one or more of O, S, Se, and Te. For example, the semiconductor substrate may include Si, Ge, SiC, SiGe, SiGeC, Ge alloys, GaAs, InAs, InP, and the like, but is not limited thereto. In an embodiment, for example, the substrate 110 may be a silicon-on-insulator (SOI) substrate or a germanium-on-insulator (GOI) substrate. However, it is not limited to this and may be a glass substrate, a ceramic substrate, or a polymer substrate.

The substrate 110 may have a plurality of trenches 111. The trenches 111 may be formed at a predetermined depth from the surface of the substrate 110 and expose the inner wall of the substrate 110. The depth of the trench may be, for example, about 10 nm to about 500 nm, about 10 nm to about 400 nm, about 10 nm to about 300 nm, about 10 nm to about 200 nm, about 10 nm to 180 nm, about 20 nm to about 500 nm, about 20 nm to about 400 nm, about 20 nm to about 300 nm, about 20 nm to about 200 nm, or about 20 nm to 180 nm.

The shape of the trench 111 is not particularly limited, and for example, the connecting portion between the bottom surface and the side surface of the trench 111 may be round, or the side surface of the trench 111 may be inclined at a predetermined angle, among other shapes.

The gate insulating film 120 may be positioned along the inner wall of the substrate 110 in the trench 111. In an embodiment, the gate insulating film 120 may be a thin film, for example, a continuous thin film formed with a substantially uniform thickness along the inner wall of the substrate 110 in the trench 111. In an embodiment, the gate insulating film 120 may have a thickness of, for example, about 1 nm to about 30 nm, for example, about 3 nm to about 20 nm, for example, about 5 nm to about 10 nm.

In an embodiment, the gate insulating film 120 may be, for example, an oxide film and may include, for example, a metal oxide or a semi-metal oxide. In an embodiment, the metal oxide or semi-metal oxide may include, for example, silicon oxide, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, and/or lead scandium tantalum oxide, but is not limited thereto. In an embodiment, for example, the gate insulating film 120 may include silicon oxide and may be, for example, the afore- mentioned thin film.

The diffusion barrier film 130 may be positioned on the gate insulating film 120 along the inner wall of the substrate 110 in the trench 111. In embodiments, the diffusion barrier film 130 may be a continuous thin film formed with a substantially uniform thickness along the inner wall of the substrate 110, for example, in the trench 111. In embodiments, the diffusion barrier film 130 may be the afore-mentioned thin film, and may be, for example, a nitride, oxide, or oxynitride including Ti, Ta, W, Zr, Zn, Mo, Nb, Al, V, Co, Ni, Cu, Hf, La, Ce, Nd, Si, Ge, or a combination thereof, and may be, for example, TiN. As described above, the diffusion barrier film 130 may be a high-purity thin film that effectively reduces precursor residues, etc. during the deposition process. In an embodiment, the diffusion barrier film 130 may have a thickness of, for example, about 1 nm to about 30 nm, for example, about 3 nm to about 20 nm, for example, about 3 nm to about 10 nm.

The gate electrode 140 may be disposed in the trench 111. The gate electrode 140 may be in contact with the diffusion barrier film 130 and may fill the trench 111 or a portion of the trench 111. In an embodiment, the gate electrode 140 may be, for example, tungsten (W), copper (Cu), molybdenum (Mo), an alloy thereof, or a combination thereof, but is not limited thereto. The thickness of the gate electrode 140 may be, for example, about 1 nm to about 50 nm, about 1 nm to about 40 nm, about 1 nm to about 30 nm, about 1 nm to about 20 nm, about 1 nm to 10 nm, about 2 nm to about 50 nm, about 2 nm to about 40 nm, about 2 nm to about 30 nm, about 2 nm to about 20 nm, or about 2 nm to 10 nm.

The source electrode 150 and the drain electrode 160 may be disposed on both sides of the trench 111 and may be, for example, a conductive region doped with impurities. The source electrode 150 and the drain electrode 160 have higher conductivity than the substrate 110. In an embodiment, for example, when the semiconductor device 100 is an n-type transistor, the source electrode 150 and the drain electrode 160 may be highly doped with n-type impurities, and when the semiconductor device 100 is a p-type transistor, the source electrode 150 and the drain electrode 160 may be highly doped with p-type impurities. In an embodiment, the n-type impurity or the p-type impurity may be included at a concentration of, for example, about 10¹⁵/cm³ or more, but is not limited thereto.

Hereinafter, the embodiments are illustrated in more detail with reference to examples. However, these examples are exemplary, and the present scope is not limited thereto.

### Formation of Thin Films

### Reference Example

A SiO₂ substrate (substrate temperature: 400° C.) is placed in a deposition chamber set to a pressure of about 1 Torr, and an atomic layer deposition (ALD) process is performed for 600 cycles in total with 1 cycle (each cycle) consisting of injecting a TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds (a deposition thickness per cycle: 0.39 Å) to form a TiN thin film.

### Example 1

A SiO₂ substrate (substrate temperature: 400° C.) is placed in a deposition chamber set to a pressure of about 1 Torr, and the atomic layer deposition (ALD) process is performed for 5 cycles in total with 1 cycle (each cycle) consisting of injecting a TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds. Subsequently, a super cycle is performed where 1 cycle (each cycle) consists of injecting the TiCl₄ precursor (5° C.) for 0.2 seconds, purging with Ar gas at a flow rate of 400 sccm for 10 seconds, injecting HBr at a flow rate of 50 sccm for 0.5 seconds, purging with Ar gas at a flow rate of 1400 sccm for 10 seconds, injecting NH₃ gas at a flow rate of 400 sccm for 7 seconds, and purging with Ar gas at a flow rate of 400 sccm for 10 seconds (a deposition thickness per cycle: 0.25 Å, deposition thickness per super cycle: 1.5 Å). The super cycle is 75 cycles in total performed to form a TiN thin film.

### Example 2-1

A TiN thin film is formed in the same manner as in Example 1 except that the super cycle is 100 cycles in total performed.

### Example 2-2

A TiN thin film is formed in the same manner as in Example 1 except that the TiCl₄ injection (5° C.) is changed to 0.5 seconds, and the NH₃ gas injection is changed to 10 seconds in the super cycle.

### Example 2-3

A TiN thin film is formed in the same manner as in Example 1 except that the HBr injection is changed to 1 second in each cycle.

### Example 2-4

A TiN thin film is formed in the same manner as in Example 1 except that the TiCl₄ injection (5° C.) is changed to 0.5 seconds, and the NH₃ gas injection is changed to 5 seconds in each cycle.

### Example 2-5

A TiN thin film is formed in the same manner as in Example 1 except that the NH₃ gas injection is changed to 5 seconds in each cycle.

### Example 2-6

A TiN thin film is formed in the same manner as in Example 1 except that the HBr gas injection is changed to 0.3 seconds in each cycle.

### Example 2-7

A TiN thin film is formed in the same manner as in Example 1 except that the NH₃ gas injection is changed to 3 seconds in each cycle.

### Example 3

A SiO₂ substrate (substrate temperature: 400° C.) is placed in a deposition chamber set to a pressure of about 1 Torr, and the atomic layer deposition (ALD) process is performed for 3 cycles in total with 1 cycle (each cycle) consisting of injecting a TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds. Subsequently, a super cycle is performed with 1 cycle consisting of injecting the TiCl₄ precursor (5° C.) for 0.2 seconds, purging with Ar gas at a flow rate of 400 sccm for 10 seconds, injecting HBr at a flow rate of 50 sccm for 0.5 seconds, purging with Ar gas at a flow rate of 1400 sccm for 10 seconds, injecting NH₃ gas at a flow rate of 400 sccm for 7 seconds, and purging with Ar gas at a flow rate of 400 sccm for 10 seconds (a deposition thickness per cycle: 0.25 Å, a deposition thickness per super cycle: 0.34 Å). The super cycle is 150 cycles in total performed to form a TiN thin film.

### Example 4

A SiO₂ substrate (substrate temperature: 400° C.) is placed in a deposition chamber set to a pressure of about 1 Torr, and the atomic layer deposition (ALD) process is performed for 1 cycle of injecting the TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds. Subsequently, a super cycle is performed with 1 cycle (each cycle) consisting of injecting the TiCl₄ precursor (5° C.) for 0.2 seconds, purging with Ar gas at a flow rate of 400 sccm for 10 seconds, injecting HBr at a flow rate of 50 sccm for 0.5 seconds, purging with Ar gas at a flow rate of 1400 sccm for 10 seconds, injecting NH₃ gas at a flow rate of 400 sccm for 7 seconds, and purging with Ar gas at a flow rate of 400 sccm for 10 seconds (a deposition thickness per cycle: 0.25 Å, a deposition thickness per super cycle: 0.23 Å). The super cycle is 300 cycles in total performed to form a TiN thin film.

### Example 5

A SiO₂ substrate (substrate temperature: 400° C.) is placed in a deposition chamber set to a pressure of about 1 Torr, and the atomic layer deposition (ALD) process is performed for 7 cycles in total with 1 cycle (each cycle) consisting of injecting the TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds. Subsequently, a super cycle is performed with 1 cycle consisting of injecting the TiCl₄ precursor (5° C.) for 0.2 seconds, purging with Ar gas at a flow rate of 400 sccm for 10 seconds, injecting HBr at a flow rate of 50 sccm for 0.5 seconds, purging with Ar gas at a flow rate of 1400 sccm for 10 seconds, injecting NH₃ gas at a flow rate of 400 sccm for 7 seconds, and purging with Ar gas at a flow rate of 400 sccm for 10 seconds (a deposition thickness per cycle: 0.25 Å, a deposition thickness per super cycle: 0.35 Å). The super cycle is 75 cycles in total performed to form a TiN thin film.

### Example 6

A SiO₂ substrate (substrate temperature: 400° C.) is placed in a deposition chamber set to a pressure of about 1 Torr, and the atomic layer deposition (ALD) process is performed for 5 cycles in total with 1 cycle (each cycle) consisting of injecting the TiCl₄ precursor (5° C.) for 0.2 seconds, purging with Ar gas at a flow rate of 400 sccm for 10 seconds, injecting NH₃ gas at a flow rate of 1400 sccm for 7 seconds, and purging with Ar gas at a flow rate of 400 sccm for 10 seconds. Subsequently, a super cycle is performed with 1 cycle (each cycle) consisting of injecting the TiCl₄ precursor (5° C.) for 0.2 seconds, purging with Ar gas at a flow rate of 400 sccm for 10 seconds, injecting HBr at a flow rate of 50 sccm for 0.5 seconds, purging with Ar gas at a flow rate of 1400 sccm for 10 seconds, injecting 12 at a flow rate of 100 sccm for 0.5 seconds, and purging with Ar gas at a flow rate of 1400 sccm for 10 seconds, injecting NH₃ gas at a flow rate of 400 sccm for 7 seconds, and purging with Ar gas at a flow rate of 400 sccm for 10 seconds. The super cycle is 100 cycles in total performed to form a TiN thin film.

### Evaluation I

The TiN thin films according to the Examples and the Reference Example are analyzed with respect to their components.

The components of each of the thin films are analyzed by using transmission electron microscopy with energy-dispersive X-ray spectroscopy (TEM-EDS, Model JEM-2100F, JEOL Ltd.).

The results are shown in Table 1.

TABLE 1

| | CI (at %) | Br (at %) | C (at %) |
|---|---|---|---|
| Reference Example | 2.84 | — | 0 |
| Example 1 | 0.52 | N/L | 0 |
| Example 2-1 | 0.42 | N/L | 0 |
| Example 2-2 | 0.81 | N/L | 0 |
| Example 2-3 | 0.80 | N/L | 0 |
| Example 2-4 | 1.05 | N/L | 0 |
| Example 2-5 | 1.11 | N/L | 0 |
| Example 2-6 | 1.41 | N/L | 0 |
| Example 2-7 | 1.78 | N/L | 0 |
| Example 3 | 0.59 | N/L | 0 |
| Example 4 | 0.51 | 0.23 (2300 ppm) | 0 |
| Example 5 | 0.73 | N/L | 0 |
| Example 6 | 0.24 | N/L | 0 |

* N/L: Noise Level (≤1 ppm)

### Evaluation II

The TiN thin films according to the Examples and the Reference Example are evaluated with respect to electrical characteristics.

The electrical characteristics are evaluated by resistivity, and the resistivity is evaluated by depositing each of the TiN thin films on a substrate with a square size (10 mm×10 mm) to measure sheet resistance with a sheet resistance meter (Model CMT-SR1000N, AiT Co, Ltd.) and then, multiplying the sheet resistance with a thickness of the thin film to convert it to resistivity.

The resistivity is expressed as a relative value based on the resistivity (Ref.) of the thin film according to the Reference Example.

The results are shown in Table 2.

TABLE 2

| | Resistivity |
|---|---|
| Reference Example | 100 (Ref.) |
| Example 1 | 75 |
| Example 2-1 | 61 |
| Example 2-2 | 74 |
| Example 2-3 | 61 |
| Example 2-4 | 62 |
| Example 2-5 | 62 |
| Example 2-6 | 72 |
| Example 6 | 55 |

Referring to Table 2, the thin films according to the embodiments of the Examples are confirmed to advantageously have less influence from impurities than the thin film according to the Reference Example, and thus advantageously exhibit satisfactory electrical characteristics.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A method for forming a thin film, comprising:
supplying a precursor including a metal or semi-metal element and a first halogen onto a substrate configured for a semiconductor device,
supplying an inorganic additive including a second halogen different from the first halogen excluding iodine and configured to spontaneously substitute the first halogen of the precursor at a predetermined temperature, and
supplying a reactant configured to chemically bond to the metal or semi-metal element, forming the thin film.

2. The method of claim 1, wherein
the first halogen is fluorine (F), chlorine (CI), or a combination thereof, and
the second halogen is bromine (Br).

3. The method of claim 2, wherein the inorganic additive comprises hydrogen bromide (HBr), dibromine (Br₂), or a combination thereof.

4. The method of claim 1, wherein the thin film comprises a nitride, oxide, or oxynitride including the metal or semi-metal element.

5. The method of claim 4, wherein
the precursor is a fluoride or chloride including titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof, and
the thin film comprises a nitride, oxide or oxynitride including titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof.

6. The method of claim 1, wherein the reactant comprises ammonia (NH₃), dihydrogen (H₂), water (H₂O), dioxygen (O₂), ozone (O₃), or a combination thereof.

7. The method of claim 1, wherein a supplied amount of the inorganic additive is less than a supplied amount of the precursor.

8. The method of claim 1, wherein the predetermined temperature is a process temperature of about 200° C. to about 600° C.

9. The method of claim 1, wherein the supplying of the inorganic additive is performed before the supplying of the precursor or after the supplying of the precursor.

10. The method of claim 1, further comprising supplying a reaction accelerator including a third halogen, the third halogen being different from the first halogen and the second halogen.

11. The method of claim 10, wherein the third halogen is iodine (I).

12. The method of claim 11, wherein the reaction accelerator comprises hydrogen iodine (HI), diiodine (I₂), R-I, wherein R is a substituted or unsubstituted C1 to C30 hydrocarbon group and I is iodine, or a combination thereof.

13. The method of claim 10, wherein the supplying of the reaction accelerator is performed before the supplying of the reactant.

14. The method of claim 13, wherein the supplying of the precursor, the supplying of the inorganic additive, and the supplying of the reaction accelerator are sequentially performed.

15. The method of claim 1, wherein each of the supplying of the precursor, the supplying of the inorganic additive, and the supplying of the reactant is repeated to form a plurality of atomic layers.

16. The method of claim 1, wherein a content of the first halogen in the thin film analyzed by transmission electron microscopy with energy-dispersive X-ray spectroscopy (TEM-EDS) is less than or equal to about 2.5 atomic percent (at %).

17. The method of claim 16, wherein a content of the second halogen in the thin film analyzed by transmission electron microscopy with energy-dispersive X-ray spectroscopy (TEM-EDS) is less than or equal to about 0.5 atomic percent (at %).

18. A thin film, the thin film formed by the method of claim 1,
wherein the thin film comprises:
a nitride, oxide or oxynitride including a metal or semi-metal element,
a content of fluorine (F), chlorine (Cl), or a combination thereof less than or equal to about 2.5 atomic percent (at %),
a content of bromine (Br) less than or equal to about 0.5 atomic percent (at %), and
the thin film does not include carbon.

19. The thin film of claim 18, wherein the nitride, the oxide or the oxynitride comprises titanium (Ti), tantalum (Ta), tungsten (W), zirconium (Zr), zinc (Zn), molybdenum (Mo), niobium (Nb), aluminum (Al), vanadium (V), cobalt (Co), nickel (Ni), copper (Cu), hafnium (Hf), lanthanum (La), cerium (Ce), neodymium (Nd), silicon (Si), germanium (Ge), or a combination thereof.

20. A semiconductor device comprising the thin film of claim 18.
